(19) United States
(12) Patent Application Publication
(10) Pub. No.: US 2012/0024229 A1
(43) Pub. Date: Feb. 2, 2012

(54) CONTROL OF PLASMA PROFILE USING MAGNETIC NULL ARRANGEMENT BY AUXILIARY MAGNETS

(75) Inventors: GUOJUN LIU, San Jose, CA (US); XIANMIN TANG, San Jose, CA (US); QIAN LUO, Union City, CA (US); YONG CAO, San Jose, CA (US)

(73) Assignee: APPLIED MATERIALS, INC., Santa Clara, CA (US)

(21) Appl. No.: 13/195,171

(22) Filed: Aug. 1, 2011

Related U.S. Application Data
(60) Provisional application No. 61/370,081, filed on Aug. 2, 2010.

(51) Int. Cl. C23C 16/511; H01F 7/02

(52) U.S. Cl. 118/723 MA; 335/306; 335/219

(57) ABSTRACT

Magnetrons for use in physical vapor deposition (PVD) chambers and methods of use thereof are provided herein. In some embodiments, an apparatus may include a support member having an axis of rotation; a plurality of first magnets coupled to the support member on a first side of the axis of rotation and having a first polarity oriented in a first direction perpendicular to the support member; and a second magnet coupled to the support member on a second side of the axis of rotation opposite the first side and having a second polarity oriented in a second direction opposite the first direction. In some embodiments, the apparatus is capable of forming a magnetic field including one or more magnetic nulls that modulate local plasma uniformity in a physical vapor deposition (PVD) chamber.

### CROSS-REFERENCE TO RELATED APPLICATIONS

This application claims benefit of U.S. provisional patent application Ser. No. 61/370,081, filed Aug. 2, 2010, which is herein incorporated by reference.

### FIELD

Embodiments of the present invention generally relate to substrate processing, and more specifically to substrate processing in physical vapor deposition chambers.

### BACKGROUND

In semiconductor processing, physical vapor deposition (PVD) is a conventionally used process for deposition of materials atop a substrate. A conventional PVD process includes bombarding a target comprising a source material with ions from a plasma, causing the source material to be sputtered from the target. The ejected source material is then accelerated towards the substrate via a negative voltage or bias formed on the substrate, resulting in a deposition of the source material atop the substrate. Following the deposition of the source material, the deposited material may then be resputtered by bombarding the substrate with ions from the plasma, thereby facilitating a redistribution of the material about the substrate.

During the PVD process a magnetron may be rotated near a backside of the target to promote uniformity of the plasma. However, during some PVD processes using certain materials, the inventors have observed the target may become magnetized. This magnetization of the target may undesirably affect the plasma uniformity, thereby creating a non-uniform deposition or resputtering of the source material. For example, the plasma may comprise a profile having a bimodal ion distribution profile, resulting in a non-uniform material deposition due to a low resputtering ratio at the center of the substrate.

Therefore, the inventors have provided an improved magnetron for use in a PVD chamber.

### SUMMARY

Magnetrons for use in physical vapor deposition (PVD) chambers and methods of use thereof are provided herein. In some embodiments, an apparatus may include a support member having an axis of rotation; a plurality of first magnets coupled to the support member on a first side of the axis of rotation and having a first polarity oriented in a first direction perpendicular to the support member; and a second magnet coupled to the support member on a second side of the axis of rotation opposite the first side and having a second polarity oriented in a second direction opposite the first direction. In some embodiments, the apparatus is capable of forming a magnetic field including one or more magnetic nulls that modulate local plasma uniformity in a physical vapor deposition (PVD) chamber.

In some embodiments, a physical vapor deposition processing system may include a chamber having a substrate support for supporting a substrate disposed therein; a target disposed within the chamber, opposite the substrate support; and a magnetron disposed proximate a backside of the target, opposite the substrate support. The magnetron may include a support member having an axis of rotation; a plurality of first magnets coupled to the support member on a first side of the axis of rotation and having a first polarity oriented in a first direction perpendicular to the support member; and a second magnet coupled to the support member on a second side of the axis of rotation opposite the first side and having a second polarity oriented in a second direction opposite the first direction. In some embodiments, the magnetron is capable of forming a magnetic field including one or more magnetic nulls that modulate local plasma uniformity in the chamber.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is schematic side view of a physical vapor deposition chamber having a magnetron in accordance with some embodiments of the present invention.

FIG. 1A depicts a graph of plasma uniformity profile as a function of varying distance between a substrate and a target in a process chamber.

FIG. 2 is a schematic bottom view of a magnetron for use in a physical vapor deposition (PVD) chamber in accordance with some embodiments of the present invention.

FIGS. 3-6 depict plasma uniformity profiles for magnetrons in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to magnetrons for use with physical vapor deposition (PVD) chambers and PVD chambers using such magnetrons. In some embodiments, the inventive magnetron may advantageously increase the uniformity of a plasma formed within a process chamber by offsetting the effects of a magnetized target during PVD processing. Embodiments of the present invention may further advantageously improve substrate processing by providing uniform plasma sputtering of a target and uniform resputtering of target material deposited atop a substrate.

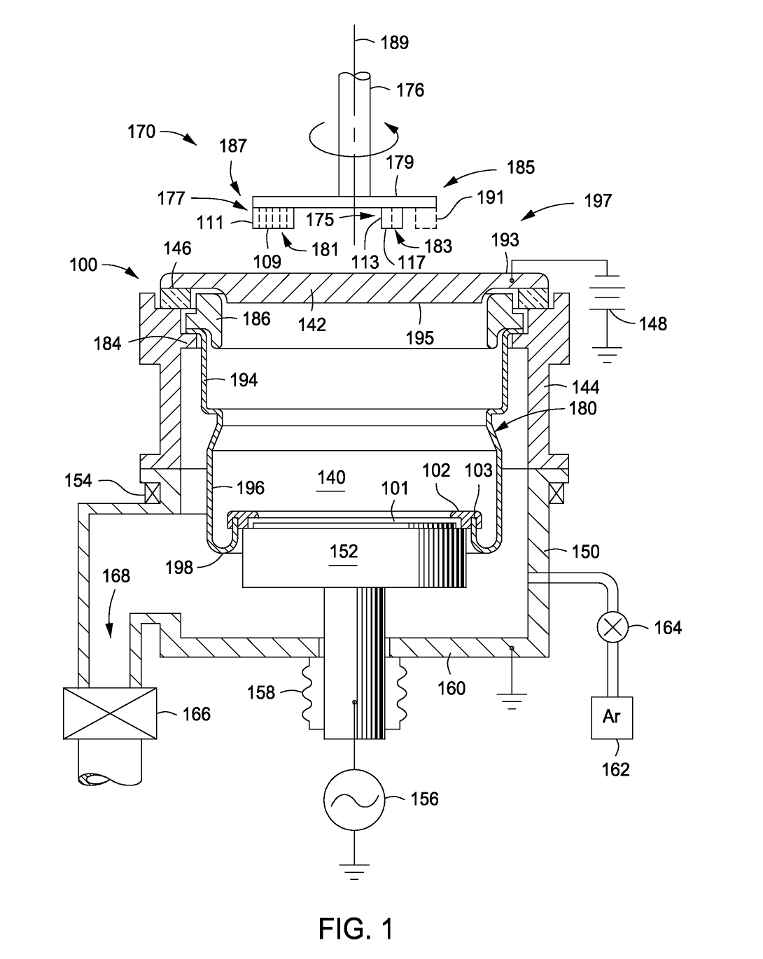

FIG. 1 is a process chamber suitable for use with a magnetron in accordance with some embodiments of the present invention. Examples of suitable PVD chambers include the ALPS® Plus and SIP ENCORE® PVD processing chambers, both commercially available from Applied Materials, Inc., of Santa Clara, Calif. It is contemplated that other processing chambers from other manufactures may also be utilized to perform the present invention.

In some embodiments, the process chamber 100 contains a substrate support pedestal 152 for receiving the substrate 101 thereon, and a sputtering source, such as a target 142. The substrate support pedestal 152 may be located within a grounded enclosure, which may be a chamber wall 150 (as shown) or a grounded shield (not shown).

The target 142 may be supported on a grounded conductive aluminum adapter 144 through a dielectric isolator 146. The target 142 may comprise any material to be deposited on the substrate 101 during sputtering. In some embodiments, for example, where the material is deposited to form a layer (e.g., gate layer, source region, drain region, or the like) of a metal oxide semiconductor (MOS) integrated circuit, the target 142 may comprise a metal. For example, in some embodiments, such as where a cobalt silicide (CoSi₂) layer is to be formed atop the substrate 101, the target 142 may comprise cobalt (Co).

The substrate support pedestal 152 has a material-receiving surface facing the principal surface of the target 142 and supports the substrate 101 to be sputter coated in planar position opposite to the principal surface of the target 142. The substrate support pedestal 152 may support the substrate 101 in a central region 140 of the process chamber 100. The central region 140 is defined as the region above the substrate support pedestal 152 during processing (for example, between the target 142 and the substrate support pedestal 152 when in a processing position).

The substrate support pedestal 152 is vertically movable through a bellows 158 connected to a bottom chamber wall 160 to allow the substrate 101 to be transferred onto the substrate support pedestal 152 through a load lock valve (not shown) in the lower portion of the process chamber 100 and thereafter raised to a deposition, or processing position as depicted in FIG. 1. One or more process gases may be supplied from a gas source 162 through a mass flow controller 164 into the lower part of the process chamber 100. The process gases may be any gases suitable for use with the particular process being performed, for example any reactive or non reactive gases. For example, in some embodiments a non-reactive gas may be supplied in the deposition gas mixture to facilitate maintaining a plasma and/or providing additional ions to the plasma that may be accelerated towards the target 142 to assist sputtering the material from the target 142. Examples of non-reactive gases include, but are not limited to, argon (Ar), helium (He), xenon (Xe), krypton (Kr), and the like. An exhaust port 168 may be provided and coupled to a pump (not shown) via a valve 166 for exhausting the interior of the process chamber 100 and facilitating maintaining a desired pressure inside the process chamber 100.

A controllable DC power source 148 may be coupled to the process chamber 100 to apply a negative voltage, or bias, to the target 142. In some embodiments, the controllable DC power source 148 may provide about 1000 to about 38 kW, or in some embodiments, about 40 kW of power, to the target 142. An RF power supply 156 may be coupled to the substrate support pedestal 152 in order to induce a negative DC bias on the substrate 101. In some embodiments, the RF power supply 156 may provide about 0 to about 1250 W, or in some embodiments, about 1250 W of power, to the substrate support pedestal 152. In addition, in some embodiments, a negative DC self-bias may form on the substrate 101 during processing. In other applications, the substrate support pedestal 152 may be grounded or left electrically floating.

In operation, power supplied from the controllable DC power source 148 may be applied to a process gas (e.g., the process gases described above) supplied by the gas source 162 to the process chamber 100 causing the process gas to ignite, thereby forming a plasma. Ions from the plasma are accelerated towards the target 142, sputtering material from the target 142. The ejected target material is then accelerated towards the substrate 101 via a negative voltage or bias formed on the substrate 101 (e.g., via power supplied to substrate support pedestal 152 from the RF power supply 156 or a negative DC self-bias, described above) facilitating deposition of the target material atop the substrate 101.

The process chamber 100 further includes a grounded bottom shield 180 connected to a ledge 184 of the adapter 144. A dark space shield 186 is supported on the bottom shield 180 and is fastened to the shield 180 by screws or other suitable manner. The metallic threaded connection between the bottom shield 180 and the dark space shield 186 allows the two shields 180, 186 to be grounded to the adapter 244. The adapter 244 in turn is sealed and grounded to the aluminum chamber wall 150. Both shields 180, 186 are typically formed from hard, non-magnetic stainless steel.

The bottom shield 180 extends downwardly in an upper tubular portion 194 of a first diameter and a lower tubular portion 196 of a second diameter. The bottom shield 180 extends along the walls of the adapter 144 and the chamber wall 150 downwardly to below a top surface of the substrate support pedestal 152 and returns upwardly until reaching a top surface of the substrate support pedestal 152 (e.g., forming a u-shaped portion 198 at the bottom). A cover ring 102 rests on the top of the upwardly extending inner portion 103 of the bottom shield 180 when the substrate support pedestal 152 is in its lower, loading position but rests on the outer periphery of the substrate support pedestal 152 when it is in its upper, deposition position to protect the substrate support pedestal 152 from sputter deposition. An additional deposition ring (not shown) may be used to shield the periphery of the substrate 101 from deposition.

In some embodiments, a magnet 154 may be disposed about the process chamber 100 for selectively providing a magnetic field between the substrate support pedestal 152 and the target 142. In some embodiments, the magnet 154 may be disposed about the outside of the chamber wall 150 in a region just above the substrate support pedestal 152 when in processing position. The magnet 154 may be a permanent magnet or an electromagnet and may be coupled to a power source (not shown) for controlling the magnitude of the magnetic field generated by the electromagnet.

A magnetron 170 is disposed proximate the top 197 of the process chamber 100. The magnetron 170 may be positioned in any manner suitable to provide an adequate magnetic field capable of manipulating a plasma within the process chamber 100. For example, in some embodiments, the magnetron 170 is positioned proximate a back surface 193 of the target 142. Generally, the magnetron 170 produces a magnetic field within the process chamber 100 proximate a front surface 195 of the target 142 to trap electrons and increase a local plasma density, thereby facilitating an increased sputtering rate of material ejected from the target.

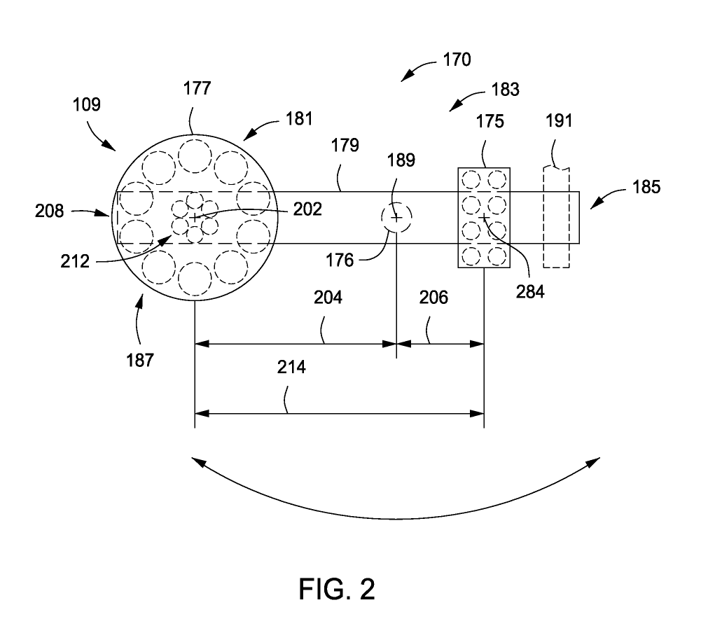

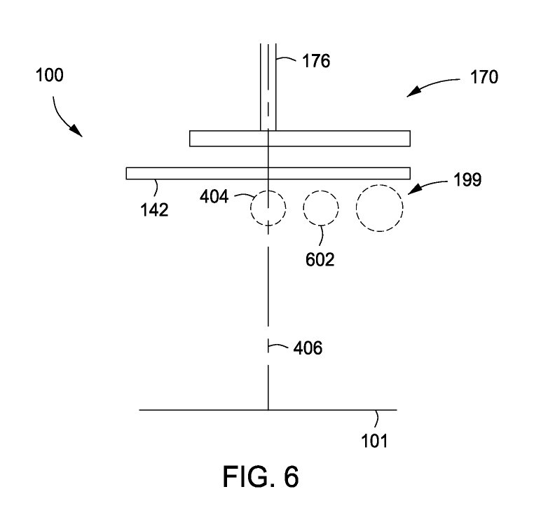

Referring to FIG. 1A, in some embodiments, the inventors have observed that by varying the distance H between the target 142 and substrate 101 a uniformity profile of the plasma formed (i.e., plasma profile 104, 108) may be affected. For example, in some embodiments, such as where the magnetron 170 produces a magnetic field having a single magnetic null 199, as the distance H between the target 142 and substrate is increased from a first distance H1 to a second distance H2, the plasma profile may change from having a peak 112 proximate the edge 105 (e.g., plasma profile 104) to a center peak plasma profile, having a peak 114 proximate the center 110 (e.g., plasma profile 108). Although FIG. 1A is described as having only one magnetic null 199 present, the amount of magnetic nulls may vary, for example, as described below with respect to FIGS. 3-6.

Referring back to FIG. 1, in some embodiments, the magnetron 170 generally comprises a support member 179 having an axis of rotation 189, a plurality of first magnets 181 and a second magnet 183. The support member 179 may be coupled to a shaft 176 to facilitate rotation about the axis of rotation 189 positioned coincident with the central axis of the chamber 100 and the substrate 101. In some embodiments, for example such as depicted in FIG. 1, the plurality of first magnets 181 may be coupled to the support member 179 on a first side 187 of the axis of rotation 189. In such embodiments, the second magnet 183 may be coupled to the support member 179 on a second side 185 of the axis of rotation 189, opposite the first side.

The support member 179 may be constructed from any material suitable to provide adequate mechanical strength to secure the plurality of first magnets 181 and second magnet 183 in a static position. For example, in some embodiments, the support member 179 may be constructed from a non-magnetic metal, such as non-magnetic stainless steel. The support member 179 may have any shape suitable to allow the plurality of first magnets 181 and the second magnet 183 to be coupled thereto in a desired position. For example, in some embodiments, the support member 179 may comprise a plate, a disk, a cross member, or the like. In addition, the support member 179 may have any dimensions suitable to allow the plurality of first magnets 181 and the second magnet 183 to be positioned at a desired location with respect to the process chamber 100 and/or target 142. For example, in embodiments where the support member 179 is a cross member having a rectangular shape, the support member 179 may have a width of about 1.5 to about 3 inches and a length of about 5 to about 7 inches.

The axis of rotation 189 may be located at any position across the support member 179. For example, in some embodiments, the axis of rotation 189 may be disposed proximate a midpoint of the support member 179. Alternatively, in some embodiments, for example as depicted in FIG. 1, the axis of rotation 189 may be offset from the midpoint of the support member 179.

In some embodiments, a counterweight 191 may be coupled to the support member on the second side of the axis of rotation to provide a substantially equal total mass on both sides of the axis of rotation 189, thereby preventing or limiting eccentric rotation of the magnetron 170. In some embodiments, the counterweight 191 may be disposed radially outward from the second magnet 183. The counterweight 191 may have any size or shape suitable to provide the aforementioned weight distribution. In addition, the counterweight 191 may be constructed of any suitable material, for example a non-ferromagnetic metal such as copper.

In some embodiments, the plurality of first magnets 181 and the second magnet 183 may each be enclosed in a first housing 177 and second housing 175, respectively. When present, the first housing 177 and second housing 175 may prevent physical damage to the plurality of first magnets 181 and the second magnet 183 and facilitate coupling of the plurality of first magnets 181 and the second magnet 183 to the support member 179. The first housing 177 and second housing 175 may be constructed of any material suitable to provide adequate protection and support while not interfering or altering the magnetic field produced by the plurality of first magnets 181 and the second magnet 183. In some embodiments, the first housing 177 and second housing 175 may each respectively comprise a bottom plate 109, 117, sides 111, 113 and a top plate. The top plates may be coupled to the support member 179. In some embodiments, the support member may comprise a mechanism (not shown), for example a slot or plurality of through holes, to facilitate movement of the plurality of first magnets 181 and the second magnets to different positions along the support member 179.

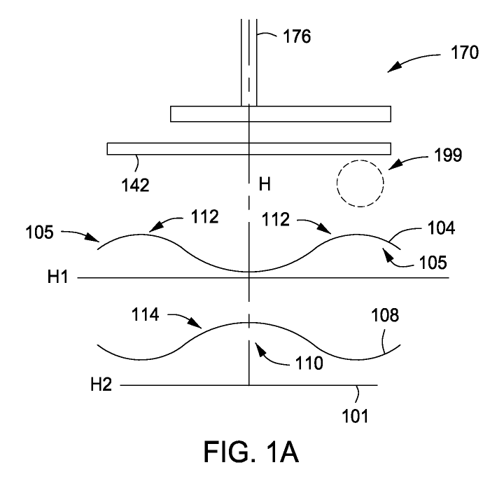

Referring to FIG. 2, the plurality of first magnets 181 may comprise any amount of magnets suitable to provide a desired magnetic field within a process chamber (e.g., process chamber 100 described above). For example in some embodiments, the plurality of first magnets 181 may comprise about 30 to about 50 magnets, or in some embodiments about 60 magnets. In some embodiments, the plurality of first magnets 181 may cumulatively generate a magnetic field having a strength of about 200 to about 500 Gauss. In addition, the plurality of first magnets 181 may be configured in any manner to provide the desired magnetic field. For example, in some embodiments, the plurality of first magnets 181 may be configured in a circular pattern, such as depicted in FIG. 2. Alternatively, in some embodiments, the plurality of first magnets 181 may be configured in a cardioid pattern.

The plurality of first magnets 181 may be any type of magnets suitable to provide the desired magnetic field. For example, the plurality of first magnets 181 may be electromagnets, or in some embodiments, permanent magnets. In embodiments where the plurality of first magnets 181 are permanent magnets, the permanent magnets may comprise any ferromagnetic material, such as iron (Fe), nickel (Ni), cobalt (Co), alloys thereof, combinations thereof, or the like.

The plurality of first magnets 181 may be configured such that the polarity of the plurality of first magnets 181 are oriented perpendicular to the support member 179. For example, in some embodiments the plurality of first magnets 181 may be configured such that the north (i.e., negative) pole is oriented away from the support member 179, or in some embodiments, towards the support member 179.

In some embodiments, the plurality of first magnets 181 may comprise a first set of first magnets 208 and a second set of first magnets 212 disposed radially inward from the first set of first magnets 208. Each of the first set of first magnets 208 and a second set of first magnets 212 may comprise any amount of magnets suitable to provide a desired magnetic field within the process chamber (e.g., process chamber 100 described above). For example in some embodiments, the first set of first magnets 208 may comprise about 20 to about 40 magnets, or in some embodiments about 60 magnets. In such embodiments, the second set of first magnets 212 may comprise about 1 to about 10, or in some embodiments about 20 magnets. The first set of first magnets 208 and a second set of first magnets 212 may be configured in any manner to provide the desired magnetic field. For example, in some embodiments the first set of first magnets 208 and a second set of first magnets 212 may be configured in concentric circles centered on a center point 202, as depicted FIG. 2. Alternatively, the first set of first magnets 208 and a second set of first magnets 212 or cardioid patterns concentrically disposed about the center point 202.

The second magnets 183 may comprise any amount of magnets suitable to provide a desired magnetic field within a process chamber (e.g., process chamber 100 described above). For example in some embodiments, the second magnets 183 may comprise about 1 to about 4 magnets, or in some embodiments about 8 magnets. In addition, the second magnets 183 may be configured in any manner to provide the desired magnetic field. For example, in some embodiments, the second magnets 183 may be arranged in sequential rows, such as depicted in FIG. 2. Alternatively, in some embodiments, the plurality of second magnets 183 may be configured in a circular or cardioid pattern, such as described above with respect to the plurality of first magnets 181.

The second magnets 183 may be any type of magnets suitable to provide the desired magnetic field. For example, the second magnets 183 may be electromagnets, or in some embodiments, permanent magnets. In embodiments where the second magnets 183 are permanent magnets, the permanent magnets may comprise any ferromagnetic material, such as iron (Fe), nickel (Ni), cobalt (Co), alloys thereof, combinations thereof, or the like. In some embodiments, the second magnets 183 may comprise the same, or in some embodiments, a different material than that of the plurality of first magnets 181.

The second magnets 183 may be configured such that the polarity of the second magnets 183 are oriented perpendicular to the support member 179. For example, in some embodiments the second magnets 183 may be configured such that the north (i.e., negative) pole is oriented away from the support member 179, or in some embodiments, towards the support member 179. In some embodiments, the orientation of the poles of the second magnets 183 may depend on the orientation of the plurality of first magnets 181. For example, in embodiments where the plurality of first magnets 181 is configured such that the north (i.e., negative) pole is oriented away from the support member 179, they second magnets 183 may be oriented such that the north (i.e., negative) pole is oriented towards the support member 179.

The second magnets 183 may generate a magnetic field having any suitable strength to provide a desired interaction with the plurality of first magnets 181. For example, in some embodiments, the second magnets 183 may generate a magnetic field having a sufficient strength to offset a magnetization on a target disposed beneath the magnetron 170 that may occur during processing (e.g., target 142 of process chamber 100 described above). For example, in some embodiments, the second magnets 183 may cumulatively generate a magnetic field having a strength of about 10 to about 150 Gauss.

The plurality of first magnets 181 and the second magnets 183 may be positioned at any point of the support member 179 such that a magnetic field produced by the plurality of first magnets 181 interacts with a magnetic field produced by the second magnets 183 at a desired point beneath the magnetron 170. For example, in some embodiments, the plurality of first magnets 181 may be positioned such that a distance 204 between a center point 202 of the plurality of first magnets 181 and the axis of rotation 189 is about 60 to about 200 mm. In some embodiments the second magnet 183 may be positioned such that a distance 206 between a center point 284 of the second magnet 183 and the axis of rotation 189 is about 0 to about 150 mm, or in some embodiments, about 65 mm. In addition, the plurality of first magnets 181 and the second magnet 183 may be positioned at any point with respect to one another to achieve a desired interaction between the respective magnetic fields. For example, a distance 214 between the plurality of first magnets 181 and the second magnet 183 may be about 150 to about 300 mm. Of course, other dimensions may be used in PVD chambers having varying dimensions or configured for processing larger or smaller substrates.

In some embodiments, within the magnetic field formed within the process chamber 100, one or more magnetic nulls (one shown) 199 may be formed, as depicted in FIG. 3. The location and size of the magnetic nulls 199 may influence a shape of the plasma profile (e.g., plasma profiles 302, 304). For example, in embodiments where the target 142 comprises a non-ferromagnetic material (e.g., tantalum (Ta), copper (Cu), titanium (Ti), or the like) and the magnetron 170 produces a first magnetic null 199, the plasma profile 304 may comprise a center peak 306 profile. Alternatively, in embodiments where the target 142 comprises a ferromagnetic material (e.g., cobalt (Co), nickel (Ni), or the like) and the magnetron produces a first magnetic null 199, the plasma profile 302 may comprise one or more peaks 308 proximate the edge 310 of the plasma profile 302.

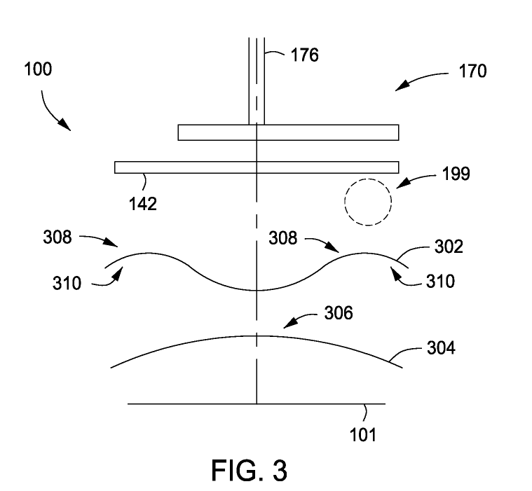

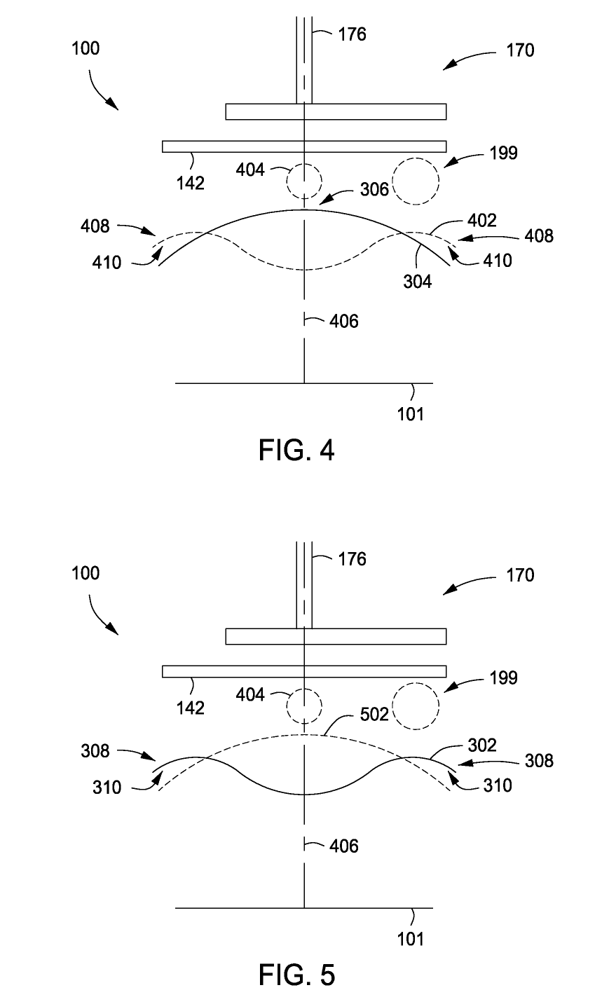

In some embodiments, the presence of additional magnetic nulls may further affect the plasma profile. For example, in embodiments where the target 142 comprises a ferromagnetic material and the magnetron 170 produces a second magnetic null 404 disposed radially inward from the first magnetic null 199 and proximate a center line 406 of the process chamber 100, the plasma profile may be inverted from a plasma profile 304 comprising a center peak 306 profile to a plasma profile 402 comprising one or more peaks 408 proximate the edge 410 of the plasma profile 402, as depicted in FIG. 4. Alternatively, in embodiments where the target 142 comprises a non-ferromagnetic material and the magnetron 170 produces a second magnetic null 404 disposed radially inward from the first magnetic null 199 and proximate a center line 406 of the process chamber 100, the plasma profile may be inverted from a plasma profile 302 comprising one or more peaks 308 proximate the edge 310 of the plasma profile 302 to a center peak 502 profile, as depicted in FIG. 5.

Although the above is described with respect to one or two magnetic nulls being formed within the process chamber it is to be noted that any amount of magnetic nulls (i.e., three or more) in any configuration, size and position with respect to the process chamber and one another may be formed to achieve the desired plasma profile. For example, in some embodiments, a third magnetic null 602 may be formed between the first magnetic null 199 and second magnetic null 404. The third magnetic null 602 may be bigger or smaller than first magnetic null 199 and second magnetic null 404 and may be positioned linearly or above or below the plane of the first magnetic null 199 and second magnetic null 404. In addition, any amount of magnets positioned in any manner about the magnetron may be utilized to produce the desired amount and location of the magnetic nulls.

Although the above is described with respect to a PVD process utilizing a target comprising magnetic materials, it is to be noted that the inventive magnetron may be utilized with any process, for example, including any PVD process depositing non-magnetic target material.

Thus, magnetrons for use in physical vapor deposition (PVD) chambers have been provided herein. In some embodiments, a magnetron having plurality of first magnets and a second magnet is provided to advantageously offset the effects of a magnetized target during PVD processing. The present invention may advantageously improve substrate processing by providing uniform plasma sputtering of a target, and therefore, provide uniform deposition of target material atop a substrate.

While the foregoing is directed to embodiments of the present invention, other and further embodiments of the invention may be devised without departing from the basic scope thereof.

1. An apparatus, comprising:
a support member having an axis of rotation;
a plurality of first magnets coupled to the support member on a first side of the axis of rotation and having a first polarity oriented in a first direction perpendicular to the support member; and
a second magnet coupled to the support member on a second side of the axis of rotation opposite the first side and having a second polarity oriented in a second direction opposite the first direction.

2. The apparatus of claim 1, wherein the apparatus is capable of forming a magnetic field including one or more magnetic nulls that modulate local plasma uniformity in a physical vapor deposition (PVD) chamber.

3. The apparatus of claim 1, wherein the plurality of first magnets and the second magnet cumulatively produce a magnetic field within a PVD chamber to control a uniformity of a plasma formed therein.

4. The apparatus of claim 1, wherein the plurality of first magnets are arranged in a cardioid or circular pattern.

5. The apparatus of claim 1, wherein the plurality of first magnets comprises a first set of first magnets configured in a cardioid or circular pattern and a second set of first magnets configured in a cardioid or circular pattern and disposed radially inward from the first set of first magnets.

6. The apparatus of claim 5, wherein a polar orientation of each of the first magnets is the same.

7. The apparatus of claim 1, wherein the second magnet comprises a plurality of second magnets.

8. The apparatus of claim 7, wherein a polar orientation of each of the plurality of second magnets is the same.

9. The apparatus of claim 1, wherein a distance between the axis of rotation of the support member and a center point of the plurality of first magnets is about 60 to about 200 mm.

10. The apparatus of claim 1, wherein a distance between the axis of rotation of the support member and a center point of the second magnet is about 0 to about 150 mm.

11. The apparatus of claim 1, wherein the support member is coupled to a shaft along the axis of rotation.

12. The apparatus of claim 11, wherein the apparatus is disposed proximate a back surface of a target disposed in a process chamber.

13. The apparatus of claim 1, wherein the support member further comprises a counterweight disposed radially outward from the second magnet.

14. The apparatus of claim 1, wherein the plurality of first magnets and the second magnet are permanent magnets.

15. The apparatus of claim 1, further comprising a third magnet coupled to the support member disposed between the plurality of first magnets and the second magnet and having a third polarity oriented in a third direction.

16. The apparatus of claim 15, wherein the third direction is the same as the first direction.

17. The apparatus of claim 15, wherein the third direction is the same as the second direction.

18. A physical vapor deposition processing system, comprising:
a chamber having a substrate support for supporting a substrate disposed therein;
a target disposed within the chamber, opposite the substrate support; and
a magnetron disposed proximate a backside of the target, opposite the substrate support, the magnetron comprising:
a support member having an axis of rotation;
a plurality of first magnets coupled to the support member on a first side of the axis of rotation and having a first polarity oriented in a first direction perpendicular to the support member; and
a second magnet coupled to the support member on a second side of the axis of rotation opposite the first side and having a second polarity oriented in a second direction opposite the first direction.

19. The system of claim 18, wherein the magnetron is capable of forming a magnetic field including one or more magnetic nulls that modulate local plasma uniformity in the chamber.
